(19) United States
(12) Patent Application Publication
(10) Pub. No.: US 2022/0173171 A1
(43) Pub. Date: Jun. 2, 2022

(54) DISPLAY DEVICE

(71) Applicant: SHARP KABUSHIKI KAISHA, Sakai City, Osaka (JP)

(72) Inventors: MASAYUKI KANEHIRO, Sakai City, Osaka (JP); SHOTA OKAMOTO, Sakai City, Osaka (JP)

(21) Appl. No.: 17/600,562

(22) PCT Filed: Apr. 8, 2019
(86) PCT No.: PCT/JP2019/015265

§ 371 Date: Sep. 30, 2021

(51) Int. Cl. H01L 27/32; H01L 51/52; H01L 51/50

(52) U.S. Cl. CPC H01L 27/3218; H01L 51/524; H01L 2251/305; H01L 27/3276; H01L 51/5072

(57) ABSTRACT

A display device includes a light-emitting element layer including a plurality of light-emitting elements. The light-emitting element layer includes, for each of the plurality of light-emitting elements, a first electrode and a plurality of openings exposing the first electrode, and includes an edge cover covering an end portion of the first electrode, a plurality of light-emitting layers covering each of the plurality of openings, and a second electrode that is common to the plurality of light-emitting elements and covers the plurality of light-emitting layers. The second electrode includes a metal nanowire. Furthermore, the light-emitting element layer includes an auxiliary wiring line provided in a lattice pattern in a position overlapping the edge cover, and the auxiliary wiring line and the metal nanowire are electrically connected to each other.

### TECHNICAL FIELD

The present invention relates to a display device including a light-emitting element.

### BACKGROUND ART

PTL 1 discloses a display device including a light-emitting element in which a cathode electrode and an electron transport layer being common to a plurality of pixel electrodes are formed.

### CITATION LIST

### Patent Literature

PTL 1: JP 2017-183510 A

### SUMMARY OF INVENTION

### Technical Problem

In general, the electron injection efficiency of the light-emitting element from the electron transport layer to the light-emitting layer varies depending on the type of light-emitting layer and electron transport layer. As in the display device described in PTL 1, when a cathode electrode and an electron transport layer are common to a plurality of light-emitting elements including different types of light-emitting layers, it is difficult to optimize the electron injection efficiency from the electron transport layer to the light-emitting layer between the plurality of light-emitting elements.

### Solution to Problem

In order to solve the problem described above, a display device according to the present application includes: a display region including a plurality of pixels; and a frame region around the display region, wherein a substrate, a thin film transistor layer, a light-emitting element layer including a plurality of light-emitting elements having luminescent colors different from each other, and a sealing layer are provided in the display region in this order, each of the plurality of light-emitting elements includes a first electrode, a hole transport layer, a light-emitting layer, an electron transport layer, and a second electrode in this order from the substrate side, the second electrode includes a metal nanowire, and the electron transport layer includes a photosensitive material and oxide nanoparticles.

### Advantageous Effects of Invention

According to the configuration described above, even when the type of light-emitting layer varies depending on the light-emitting element, it is possible to make it easier to optimize a difference in electron injection efficiency between light-emitting elements.

### BRIEF DESCRIPTION OF DRAWINGS

FIG. 1 is a top enlarged view and a side cross-sectional view of a display region of a display device according to a first embodiment.

FIG. 2 is a top perspective view of the display device according to the first embodiment.

FIG. 3 is a side cross-sectional view of a frame region of the display device according to the first embodiment.

FIG. 4 is a flowchart illustrating a manufacturing method for the display device according to the first embodiment.

FIG. 5 is a flowchart illustrating in more detail formation of a light-emitting element layer in the manufacturing method for the display device according to the first embodiment.

FIG. 6 is a step cross-sectional view illustrating the manufacturing method for the display device according to the first embodiment.

FIG. 7 is another step cross-sectional view illustrating the manufacturing method for the display device according to the first embodiment.

FIG. 8 is an energy diagram illustrating an effect achieved by the display device according to the first embodiment.

FIG. 9 is an energy diagram illustrating a difference in a band gap between pixels in an electron transport layer according to the first embodiment.

FIG. 10 is a side cross-sectional view of a display region of a display device according to each modification example.

FIG. 11 is a side cross-sectional view of a display region of a display device according to a second embodiment.

FIG. 12 is a side cross-sectional view of a display region of a display device according to a third embodiment.

FIG. 13 is a side cross-sectional view of the display region of the display device according to the third embodiment.

FIG. 14 is a side cross-sectional view of a frame region of the display device according to the third embodiment.

### DESCRIPTION OF EMBODIMENTS

### First Embodiment

In the following, “same layer” means being formed of the same material in the same process. In addition, “lower layer” means a layer that is formed in a process prior to that of a comparison layer, and “upper layer” means a layer that is formed in a process after that of a comparison layer. In this specification, a direction from a lower layer to an upper layer of a display device will be described as an upward direction.

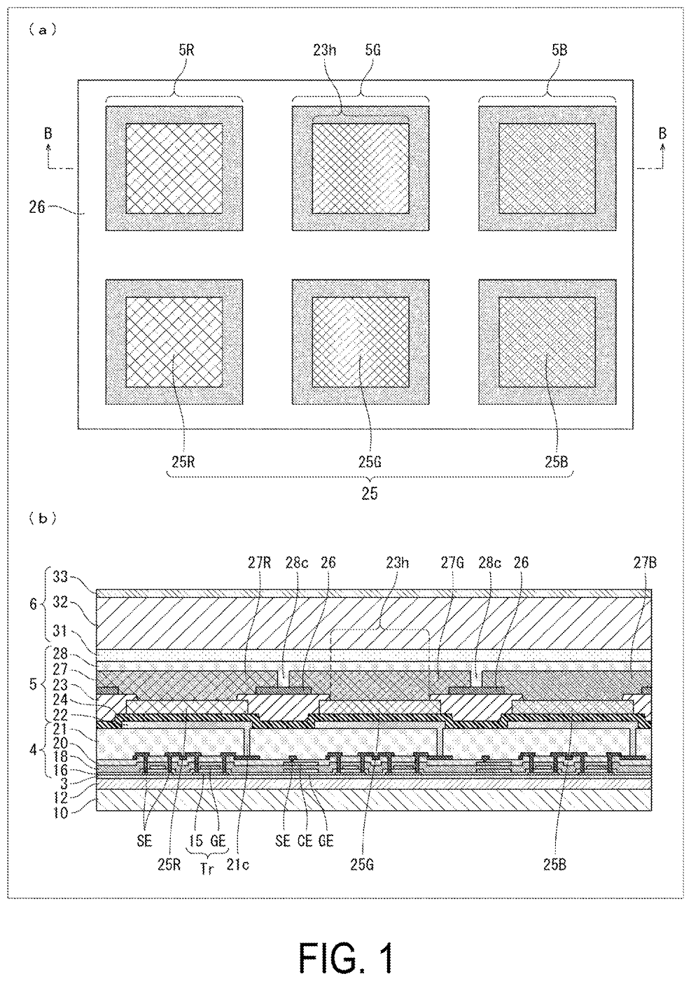

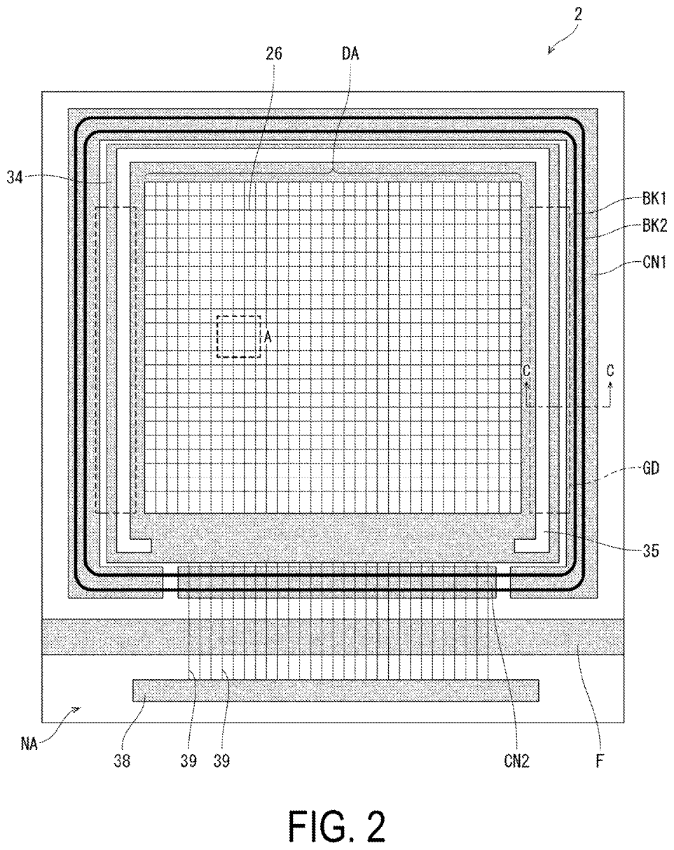

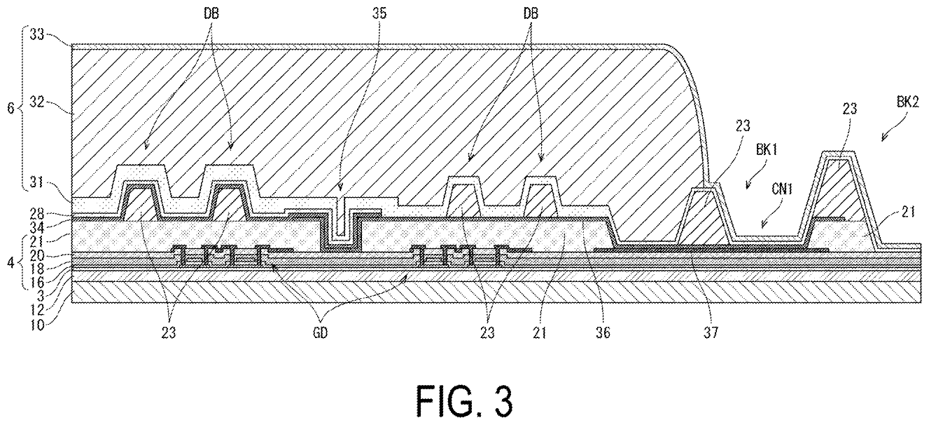

A display device 2 according to the present embodiment will be described with reference to FIGS. 1 to 3. FIG. 2 is a top view of the display device 2 according to the present embodiment. (a) of FIG. 1 is an enlarged top view of a region A in FIG. 2, and (b) of FIG. 1 is a cross-sectional view viewed in the direction of the arrows along line B-B in (a) of FIG. 1. FIG. 3 is a cross-sectional view viewed in the direction of the arrows along line C-C in FIG. 2.

As illustrated in FIG. 2, the display device 2 according to the present embodiment includes a display region DA and a frame region NA provided adjacent to the periphery of the display region DA. With reference to FIG. 1, a structure in the display region DA of the display device 2 according to the present embodiment will be explained in detail. Note that illustration of a hole transport layer 24, a second electrode 28, and a sealing layer 6, which will be described later in detail, is omitted in (a) of FIG. 1.

As illustrated in (b) of FIG. 1, the display device 2 according to the present embodiment includes a support substrate 10, a resin layer 12, a barrier layer 3, a thin film transistor layer 4, a light-emitting element layer 5, and the sealing layer 6 in this order from the lower layer. In a further upper layer overlying the sealing layer 6, the display device 2 may be provided with a function film or the like having an optical compensation function, a touch sensor function, a protection function, and the like.

The support substrate 10 may be, for example, a flexible substrate such as a PET film, or a rigid substrate such as a glass substrate. A material of the resin layer 12 may be, for example, polyimide.

The barrier layer 3 is a layer for preventing foreign matter such as water and oxygen from penetrating into the thin film transistor layer 4 and the light-emitting element layer 5 during usage of the display device. The barrier layer 3 may be constituted by, for example, a silicon oxide film, a silicon nitride film, or a silicon oxynitride which are formed by CVD, or a layered film thereof.

The thin film transistor layer 4 includes a semiconductor layer 15, a first inorganic layer 16 (gate insulating film), a gate electrode GE, a second inorganic layer 18, a capacitance wiring line CE, a third inorganic layer 20, a source wiring line SH (metal wiring line layer), and a flattening film 21 (interlayer insulating film) in this order from the lower layer. A thin-layer transistor Tr is configured to include the semiconductor layer 15, the first inorganic layer 16, and the gate electrode GE.

The semiconductor layer 15 is composed of, for example, low-temperature polysilicon (LTPS) or an oxide semiconductor. Although the thin film transistor is illustrated in FIG. 2 as having the semiconductor layer 15 as a channel and having a top gate structure, the thin film transistor may have a bottom gate structure (for example, in a case where the channel of the thin film transistor is an oxide semiconductor).

The gate electrode GE, the capacitance electrode CE, and the source wiring line SH may include, for example, at least one of aluminum (Al), tungsten (W), molybdenum (Mo), tantalum (Ta), chromium (Cr), titanium (Ti), and copper (Cu). Furthermore, the gate electrode GE, the capacitance electrode CE, or the source wiring line SH is constituted by a single-laver film or a layered film of any of the metals described above. Particularly, in the present embodiment, the gate electrode GE contains Mo, and the source wiring line SH contains Al.

The first inorganic layer 16, the second inorganic layer 18, and the third inorganic layer 20 can be configured by a silicon oxide (SiOx) film or a silicon nitride (SiNx) film, or a layered film thereof, formed using CVD, for example. The flattening film 21 can be composed of a coatable photosensitive organic material such as polyimide or acryl. A contact hole 21c is formed in a position of the flattening film 21 overlapping the source wiring line SH of the thin-layer transistor Tr.

The light-emitting element layer 5 (for example, an organic light-emitting diode layer) includes a first electrode 22 (anode electrode), the hole transport layer 24, a light-emitting layer 25, an edge cover 23 covering an edge of each light-emitting layer 25, an auxiliary wiring line 26, an electron transport layer 27, and the second electrode (cathode electrode) 28 in this order from the lower layer.

In the present embodiment, as illustrated in (a) of FIG. 1, the light-emitting element layer 5 includes, as a plurality of light-emitting elements, a red light-emitting element 5R including a red light-emitting layer 25R, a green light-emitting element 50 including a green light-emitting layer 25G, and a blue light-emitting element SB including a blue light-emitting layer 25B, The light-emitting element layer 5 includes, for each of the plurality of light-emitting elements, the first electrode 22, the light-emitting layer 25, and the electron transport layer 27 in an island shape, and further includes the hole transport layer 24 common to the plurality of light-emitting elements, and the second electrode 28 in an island shape common to the plurality of light-emitting elements.

The display device 2 includes a plurality of pixels in the display region DA, and each of the pixels includes a red subpixel, a green subpixel, and a blue subpixel as a subpixel being the smallest unit of display by the display device 2. The red subpixel includes the red light-emitting element 5R, the green subpixel includes the green light-emitting element 5G, and the blue subpixel includes the blue light-emitting element 5B.

In a plan view, the first electrode 22 is provided in a position overlapping the flattening film 21 and the contact hole 21c. The first electrode 22 is electrically connected to the source wiring line SH via the contact hole 21c. Thus, a signal in the thin film transistor layer 4 is supplied to the first electrode 22 via the source wiring line SH. Note that the thickness of the first electrode 22 may be 100 nm, for example. In the present embodiment, the first electrode 22 is formed by, for example, the layering of Indium Tin Oxide (ITO) and an alloy containing Ag and has light reflectivity.

In the present embodiment, the hole transport layer 24 is formed to be common to the plurality of light-emitting elements in an upper layer of the flattening film 21 and the first electrode 22. The hole transport layer 24 is an inorganic hole transport layer, and includes, for example, NiO or MgNiO as a hole transport material.

The light-emitting layer 25 is formed for each of the plurality of light-emitting elements in a position overlapping each of the first electrodes 22. In the present embodiment, the light-emitting layer 25 includes, for each of the plurality of light-emitting elements, the red light-emitting layer 25R, the green light-emitting layer 25G, and the blue light-emitting layer 25B described above.

In the present embodiment, the red light-emitting layer 25R, the green light-emitting layer 25G, and the blue light-emitting layer 25B emit red light, green light, and blue light, respectively. In other words, the red light-emitting element 5R, the green light-emitting element 5G, and the blue light-emitting element 5B are light-emitting elements that emit red light, green light, and blue light, respectively.

Here, the blue light refers to, for example, light having a light emission central wavelength in a wavelength band of equal to or greater than 400 nm and equal to or less than 500 nm. The green light refers to, for example, light having a light emission central wavelength in a wavelength band of greater than 500 nm and equal to or less than 600 nm. The red light refers to, for example, light having a light emission central wavelength in a wavelength band of greater than 600 nm and equal to or less than 780 nm.

The edge cover 23 is an organic insulating film, and includes an organic material such as polyimide or acryl, for example. The edge cover 23 is formed in a position covering the edge of each of the light-emitting layers 25. The edge cover 23 includes an opening 23h for each of the plurality of light-emitting elements, and a part of each of the light-emitting layers 25 is exposed from the edge cover 23. Thus, the edge cover 23 divides each pixel of the display device 2 into a red subpixel, a green subpixel, and a blue subpixel.

In the present embodiment, the auxiliary wiring line 26 is formed in a position overlapping the edge cover 23. As illustrated in (a) of FIG. 1, the auxiliary wiring line 26 is provided in a lattice pattern. In the present embodiment, the auxiliary wiring line 26 is in contact with the sealing layer 6 side of the edge cover 23. Note that, in the present embodiment, the auxiliary wiring line 26 is not limited to a shape in which the plurality of linear auxiliary wiring lines 26 arranged at substantially equal intervals perpendicularly intersect each other, as illustrated in (a) of FIG. 1. For example, like PenTile, an interval between the adjacent auxiliary wiring lines 26 may vary depending on a position, and the auxiliary wiring lines 26 may intersect each other at an angle.

A material of the auxiliary wiring line 26 may be silver. Silver is a material generally used in a backplane of a display device, such as a metal layer of the thin film transistor layer 4. Silver included in the auxiliary wiring line 26 can be used as a material for forming the backplane upon formation of the auxiliary wiring line 26. In addition, the auxiliary wiring line 26 may include Al or Cu alone, have a layered structure of Ti/Al/Ti, or have a layered structure of W/Ta.

The electron transport layer 27 is formed for each of the plurality of light-emitting elements in a position overlapping each of the first electrodes 22. In the present embodiment, the electron transport layer 27 includes an electron transport layer 27R for the red light-emitting element 5R, an electron transport layer 27G for the green light-emitting element 5G, and an electron transport layer 27B for the blue light-emitting element 5B.

In the present embodiment, the electron transport layer 27 includes a photosensitive material as a binder, and oxide nanoparticles as an electron transporting material. The photosensitive material included in the electron transport layer 27 contains a resin material and a photoinitiator. The resin material includes, for example, a polyimide resin, an acrylic resin, an epoxy resin, or a novolac resin. The photoinitiator includes, for example, a resin material, and a quinone diazide compound, a photoacid generator, or a photoradical generator.

The electron transport layer 27R is formed in a position overlapping the red light-emitting layer 25R. Thus, the red light-emitting element 5R includes the electron transport layer 27R as the electron transport layer 27. Similarly, the electron transport layer 27G is formed in a position overlapping the green light-emitting layer 25G, and the electron transport layer 27B is formed in a position overlapping the blue light-emitting layer 25B. Thus, the green light-emitting element 5G and the blue light-emitting element 5B include the electron transport layer 27G and the electron transport layer 27B as the electron transport layer 27, respectively.

The second electrode 28 is formed as a common electrode common to the plurality of light-emitting elements in an upper layer of the electron transport layer 27. The second electrode 28 includes a metal nanowire, and has high translucency. The metal nanowire included in the second electrode 28 may be, for example, a silver nanowire. In addition, the second electrode 28 may include a conductive metal nanowire such as a gold nanowire, an aluminum nanowire, or a copper nanowire. Furthermore, the second electrode 28 includes, in a position overlapping the auxiliary wiring line 26 on the edge cover 23, a contact portion 28c formed in an opening formed in the electron transport layer 27. The second electrode 28 is electrically connected to the auxiliary wiring line 26 via the contact portion 28c.

In the present embodiment, a material of the second electrode 28 may be a mixed material including a silver nanowire dispersion. Further, the mixed material may include a binder, a dispersing agent, or other additives.

The sealing layer 6 includes a first inorganic sealing film 31 above the second electrode 28, an organic sealing film 32 above the first inorganic sealing film 31, and a second inorganic sealing film 33 above the organic sealing film 32, and prevents foreign matter such as water and oxygen from penetrating into the light-emitting element layer 5. The first inorganic sealing film 31 and the second inorganic sealing film 33 can be composed of, for example, a silicon oxide film, a silicon nitride film, or a silicon oxynitride film formed by CVD, or a layered film thereof. The organic sealing film 32 can be formed of a coatable photosensitive organic material such as a polyimide or an acrylic.

Next, each configuration in the frame region NA around the display region DA will be described with reference to FIG. 2 and FIG. 3. FIG. 3 is a cross-sectional view viewed in the direction of the arrows along line C-C in FIG. 2, and illustrates each member in the frame region NA adjacent to the periphery of the display region DA of the display device 2 according to the present embodiment.

As illustrated in FIG. 3, the display device 2 may also include the support substrate 10, the resin layer 12, the barrier layer 3, the thin film transistor layer 4, and the sealing layer 6 in the frame region NA.

The display device 2 may also include, in the frame region NA, a dummy bank DB formed of the edge cover 23 illustrated in FIG. 3. The dummy bank DB may be used as a spacer used for forming a common layer in the display region DA and abutted by a CVD mask or the like.

Furthermore, the display device 2 may include, in the frame region NA, a first bank BK1 formed of the edge cover 23, and a second bank BK2 formed of the flattening film 21 and the edge cover 23, as illustrated in FIG. 2 and FIG. 3. The first bank BK1 and the second bank BK2 are formed into a frame-like shape around the display region DA. The first bank BK1 and the second bank BK2 regulate wet-spreading of the organic sealing film 32 due to coating the organic sealing film 32 with the sealing layer 6, which is a higher layer than the organic sealing film 32. For example, in FIG. 3, the first bank BK1 abuts an end portion of the organic sealing film 32 to regulate wet-spreading of the organic sealing film 32.

As illustrated in FIG. 2 and FIG. 3, the display device 2 includes a stem wiring line 34 between the flattening film 21 and the second electrode 28 in the frame region NA. The stem wiring line 34 is in the same layer as the auxiliary wiring line 26, and is formed of the same material as the auxiliary wiring line 26. As illustrated in FIG. 2, the auxiliary wiring line 26 branches from the stem wiring line 34, and extends from the frame region NA to the display region DA. As described above, the auxiliary wiring line 26 that branches from the stem wiring line 34 is formed in a lattice pattern in the position overlapping the edge cover 23 described above in the display region DA.

As illustrated in FIG. 2 and FIG. 3, a slit 35 being an opening of the flattening film 21 may be formed in the frame region NA in a position surrounding a part of the periphery of the display region DA. By forming the thin film transistor of the thin film transistor layer 4 on the display region DA side of the slit 35 and the peripheral side of the display device 2, a gate driver monolithic GD illustrated in FIG. 2 and FIG. 3 may be formed. Note that the slit 35 may not be necessarily formed.

Here, as illustrated in FIG. 3, the stem wiring line 34, together with the second electrode 28, extends farther to the peripheral side of the display device 2 than the slit 35, which includes the inside of the slit 35. As illustrated in FIG. 2, a conductive film 36 that is of the same material as that of the first electrode 22 and that is in the same layer as the first electrode 22 is formed in the frame region NA. The conductive film 36 extends from the display region DA side closer than the slit 35 in the frame region NA, passes through the inside of the slit 35, and extends farther to the peripheral side of the display device 2 than the slit 35. Thus, the stem wiring line 34 and the conductive film 36 are electrically connected to each other in a position including the inside of the slit 35.

The conductive film 36 further extends to a position overlapping the first bank BK1 and the second bank BK2. In the position overlapping the first bank BK1 and the second bank BK2, a source conductive film 37 that is the same material as the source wiring line SH of the thin film transistor layer 4 and is in the same layer is formed. Thus, the conductive film 36 and the source conductive film 37 are connected to each other at a first connection portion CN1 in a position including a portion between the first bank BK1 and the second bank BK2.

As illustrated in FIG. 2, the display device 2 includes a terminal portion 38 in the frame region NA. The terminal portion 38 is formed around the second bank BK2. A driver (not illustrated) that supplies a signal for driving each of the light-emitting elements in the display region DA via a lead wiring line 39, and the like are mounted on the terminal portion 38. In a position in which the lead wiring line 39 is formed around four sides of the display region DA, the slit 35 may not be formed.

Note that the source conductive film 37 is also formed in a position overlapping the lead wiring line 39 and overlapping the first bank BK1 and the second bank BK2. Thus, the lead wiring line 39 and the source conductive film 37 are connected to each other at a second connection portion CN2 in a position overlapping the lead wiring line 39 and including a portion between the first bank BK1 and the second bank BK2.

The source conductive film 37 at the first connection portion CN1 and the source conductive film 37 at the second connection portion CN2 are electrically conductive. Therefore, an electrical connection between a high-voltage power supply and the stem wiring line 34, and thus an electrical connection between the high-voltage power supply and the auxiliary wiring line 26 are established via the lead wiring line 39, the source conductive film 37, and the conductive film 36. Thus, the auxiliary wiring line 26 is electrically connected to both of the high-voltage power supply and the second electrode 28, and has the effect of reducing a voltage drop in the second electrode 28 in a position away from the high-voltage power supply.

Note that, when the support substrate 10 is a flexible substrate, as illustrated in FIG. 2, the display device 2 may include a bending portion F formed along an outer periphery of the display device 2 between the second bank BK2 and the terminal portion 38. In the actual display device 2, the peripheral side of the display device 2 from the bending portion F including the terminal portion 38 may be folded back to the back surface side of the display device 2 by being bent by the bending portion

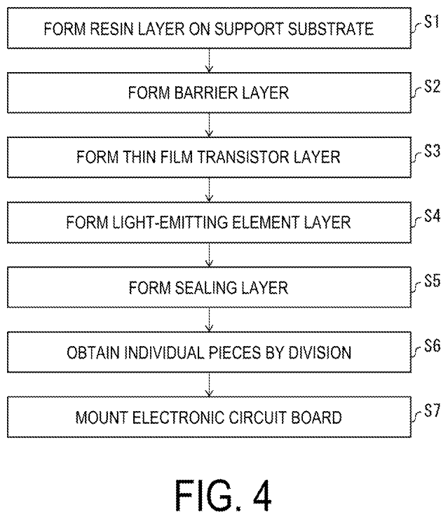

Next, a manufacturing method for the display device 2 according to the present embodiment will be described in detail with reference to FIG. 4. FIG. 4 is a flowchart illustrating each manufacturing step of the display device 2 according to the present embodiment.

First, the resin layer 12 is formed on a transparent support substrate (for example, a mother glass substrate) (step S1). Next, the barrier layer 3 is formed in an upper layer overlying the resin layer 12 (step S2). Next, the thin film transistor layer 4 is formed in an upper layer overlying the barrier layer 3 (step S3). When forming each of the layers from step S1 to step S3, a conventionally known film formation method can be employed.

Note that, in step S3, formation of the source conductive film 37 may be performed together with formation of the source wiring line SH. Further, formation of the slit 35 and formation of a part of the second bank may be performed together with formation of the flattening film 21. Furthermore, a transistor included in the gate driver monolithic GD may be formed together with formation of the thin film transistor Tr in the thin film transistor layer 4.

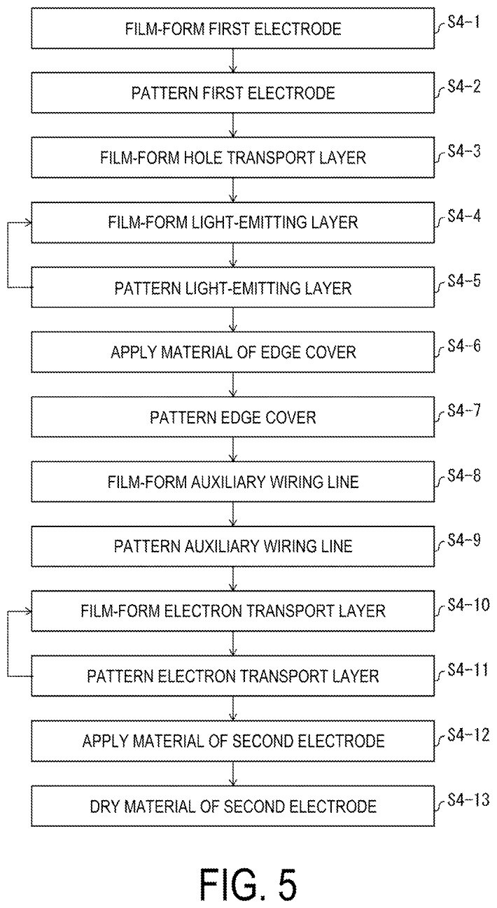

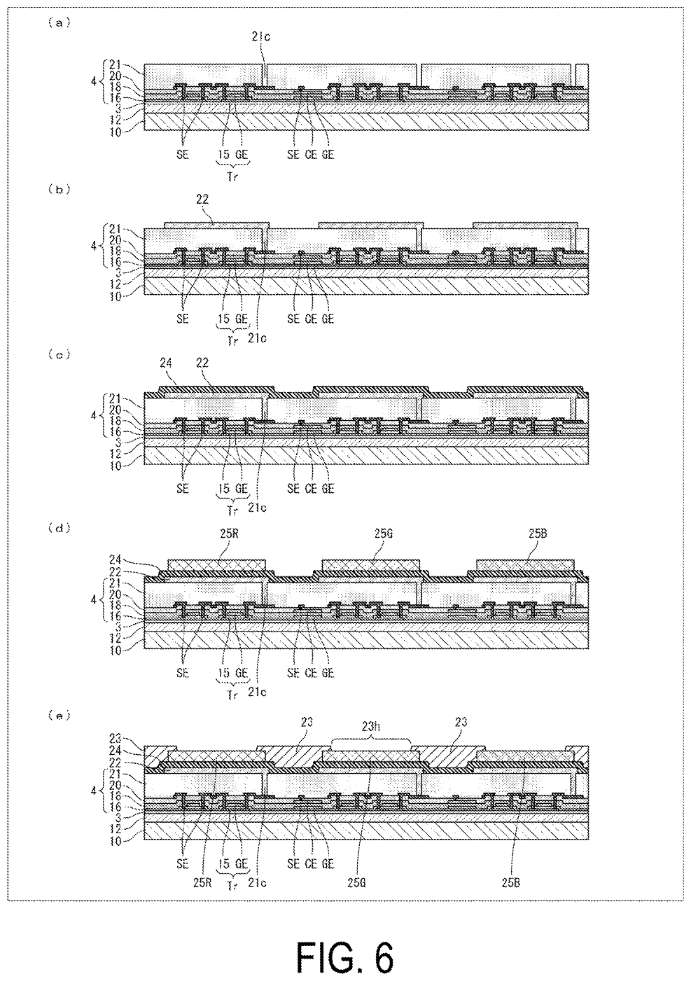

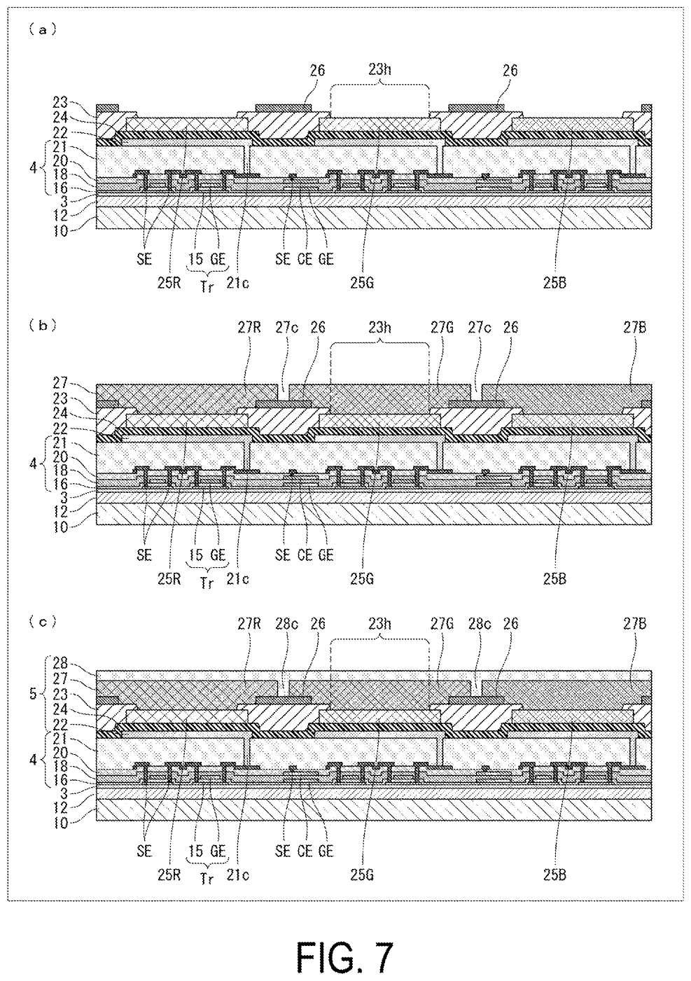

Next, the light-emitting element layer 5 is formed in an upper layer overlying the thin film transistor layer 4 (step S4). The method for forming each of the layers in step S4 will be described in more detail with reference to FIGS. 5 to 7. FIG. 5 is a flowchart illustrating the steps of forming the light-emitting element layer 5 in the present embodiment. FIG. 6 and FIG. 7 are step cross-sectional views for describing the steps of forming the light-emitting element layer 5 in more detail, which are executed based on the flowchart in FIG. 5. Note that, all subsequent step cross-sectional views including FIG. 6 and FIG. 7 illustrate step cross-sectional views in a position corresponding to (b) of FIG. 1.

Execution up to step S3 results in a structure illustrated in (a) of FIG. 6. In step S4, first, the first electrode 22 is film-formed (step S4-1). A sputtering method or the like can be employed for forming the first electrode 22. Note that, in step S4-1, film formation of the conductive film 36 is also performed.

Next, the first electrode 22 is patterned into individual electrodes (step S4-2). An etching method using photolithography or the like can be employed for patterning the first electrode 22. Execution of step S4-2 results in individual first electrodes 22 illustrated in (b) of FIG. 6. Note that, in step S4-2, patterning of the conductive film 36 is also performed.

Next, as illustrated in (c) of FIG. 6, the hole transport layer 24 is film-formed in the upper layer of the flattening film 21 and the first electrode 22 (step S4-3). For the film formation of the hole transport layer 24, a sputtering method, an application firing method using a solution coating device, such as ink-jet and various coaters, a low-temperature CVD method using a CVD mask, or the like can be used.

Next, the light-emitting layer 25 is formed. For the formation of the light-emitting layer 25, first, film formation of a light-emitting layer having any luminescent color in the light-emitting layer 25 is performed (step S4-4). For example, film formation of the red light-emitting layer 25R is performed by applying the material of the red light-emitting layer 25R to the upper layer of the hole transport layer 24.

Next, the film-formed red light-emitting layer 25R is patterned (step S4-5). Here, for example, a material in which quantum dots emitting red light are dispersed in a photosensitive material may be employed as the material of the red light-emitting layer 25R. In this way, the material of the applied red light-emitting layer 25R can be patterned by using photolithography.

Step S4-4 and step S4-5 described above are repeatedly executed according to a type of the light-emitting layer 25. In this way, each of the red light-emitting layer 25R, the green light-emitting layer 25G, and the blue light-emitting layer 25B illustrated in (d) of FIG. 6 is formed in a position overlapping each of the first electrodes 22.

Note that, in the present embodiment, a method of patterning the light-emitting layer 25 by photolithography is given as an example, but no such limitation is intended. For example, the light-emitting layer 25 may be formed by direct patterning by an ink-jet method. In the present embodiment, an example is given in which the light-emitting layer 25 includes quantum dots, but no such limitation is intended. For example, the light-emitting layer 25 may include an organic EL material. In this case, the light-emitting layer 25 may be formed by vapor deposition of the organic EL material using a vapor deposition mask.

Next, a material of the edge cover 23 is applied to an upper layer of the hole transport layer 24 and the light-emitting layer 25 (step S4-6). A conventionally known technique for applying an organic material can be employed for applying a material of the edge cover 23. The material of the edge cover 23 is also applied to the frame region NA.

Next, the edge cover 23 is patterned (step S4-7). For example, patterning of the edge cover 23 can be performed using photolithography by adding a photosensitive resin to the material of the edge cover 23.

In this way, as illustrated in (e) of FIG. 6, the edge cover 23 is obtained. Note that, by patterning the edge cover 23, a part of each of the light-emitting layers 25 except for the end portion is exposed from the opening 23h of the edge cover 23. Note that, in step S4-7, formation of the dummy bank DB and the first bank BK1 is performed. Furthermore, in step S4-7, formation of a remaining part of the second bank BK2 is performed.

Next, the auxiliary wiring line 26 is film-formed in the upper layer of the light-emitting layer 25 and the edge cover 23 (step S4-8). A sputtering method or the like can also be used for the film formation of the auxiliary wiring line 26. Note that, in step S4-8, film formation of the stem wiring line 34 is also performed.

Next, the auxiliary wiring line 26 is patterned (step S4-9). An etching method using photolithography or the like can be employed for patterning the auxiliary wiring line 26. Note that, in step S4-9, patterning of the stem wiring line 34 is also performed. In this way, as illustrated in (a) of FIG. 7, the auxiliary wiring line 26 in contact with an upper face of the edge cover 23 is formed in the upper layer of the edge cover 23.

Next, formation of the electron transport layer 27 is performed. To form the electron transport layer 27, first, film formation of an electron transport layer corresponding to any subpixel in the electron transport layer 27 is performed (step S4-10). For example, film formation of the electron transport layer 27R is performed by applying a material of the electron transport layer 27R to a position including the upper layer of the red light-emitting layer 25R.

Next, the film-formed electron transport layer 27R is patterned (step S4-11). In the present embodiment, for example, a material in which oxide nanoparticles are dispersed in a photosensitive material is employed as the material of the electron transport layer 27R. In this way, the applied material of the electron transport layer 27R can be patterned by using photolithography. Note that a developing solution used in photolithography of the electron transport layer 27 may employ TMAH or PGMEA.

Step S4-10 and step S4-11 described above are repeatedly executed according to a type of the electron transport layer 27. In this way, each of the electron transport layer 27R, the electron transport layer 27G, and the electron transport layer 27B illustrated in (b) of FIG. 7 is formed in a position overlapping the corresponding light-emitting layer 25. Here, in step S4-11, a contact hole 27c illustrated in (b) of FIG. 7 is formed by forming an opening in a position of the electron transport layer 27 overlapping the auxiliary wiring line 26. Note that, also in the step of forming the electron transport layer 27, an ink-jet method or vapor deposition may be employed.

Next, the second electrode 28 is formed. In forming the second electrode 28, first, ink including a metal nanowire is applied to the upper layer of the electron transport layer 27 (step S4-12). Next, the applied ink including the metal nanowire is dried (step S4-13) to form the second electrode 28 illustrated in (c) of FIG. 7. At this time, by also forming the second electrode 28 in a position overlapping the contact hole 27c formed in the electron transport layer 27, the contact portion 28c is formed, and an electrical connection is established between the auxiliary wiring line 26 and the second electrode 28. As described above, the steps of forming the light-emitting element layer 5 are completed.

After step S4, the sealing layer 6 is formed (step S5). Next, a layered body including the support substrate 10, the resin layer 12, the barrier layer 3, the thin film transistor layer 4, the light-emitting element layer 5, and the sealing layer 6 is divided to obtain a plurality of individual pieces (step S6). Next, an electronic circuit board (an IC chip, for example) is mounted on the terminal portion 38 to configure the display device 2 (step S7).

Note that, in the present embodiment, the transparent glass substrate described above may be used as the support substrate 10 as it is. However, by adding some steps, the flexible display device 2 can be manufactured.

For example, after step S5, a bonding force between the transparent support substrate and the resin layer 12 is reduced by irradiating the lower face of the resin layer 12 with laser light over the support substrate, and the support substrate is peeled off from the resin layer 12. Next, a lower face film such as a PET film is bonded to the lower face of the resin layer 12 to configure the support substrate 10. After that, the processing proceeds to step S6, and then, the flexible display device 2 can be obtained. In this case, the terminal portion 38 side may be folded back from the bending portion F to the back surface side of the support substrate 10 between step S6 and step S7.

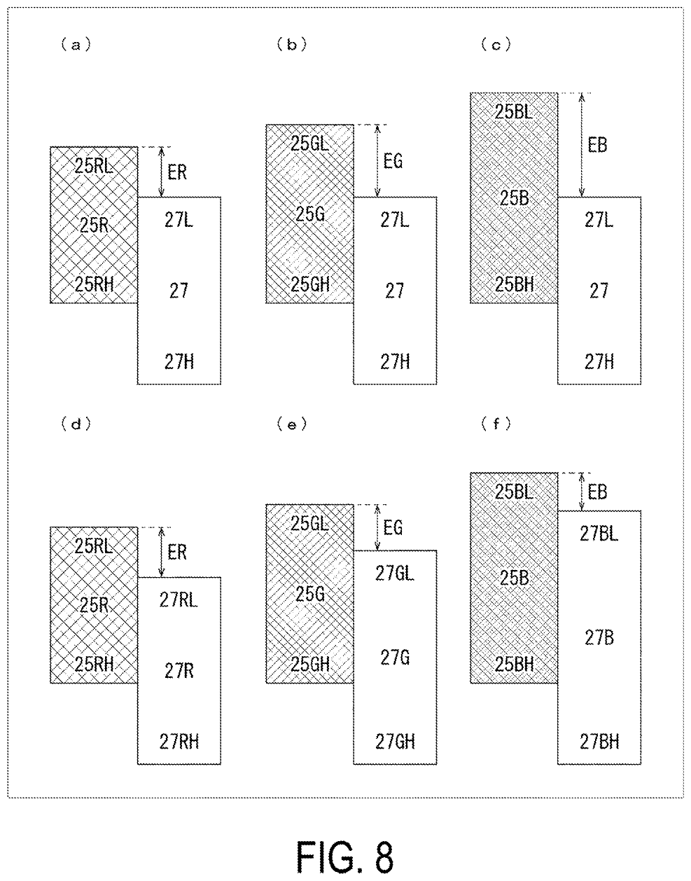

In the present embodiment, the electron transport layer 27 is formed individually for each of the light-emitting elements. Thus, even when a LUMO level of the light-emitting layer 25 varies depending on a luminescent color of the light-emitting layer 25, electron transport from the second electrode 28 to each of the light-emitting layers 25 can be more easily optimized. The description above will be described in more detail with reference to FIG. 8.

(a) to (c) of FIG. 8 are energy band diagrams each illustrating an example of a band gap in a light-emitting layer 25 and an electron transport layer 27 of a display device according to a comparative embodiment. (d) to (f) of FIG. 8 are energy band diagrams each illustrating an example of a band gap in the light-emitting layer 25 and the electron transport layer 27 of the display device 2 according to the present embodiment.

(a) of FIG. 8 and (d) of FIG. 8 illustrate an example of a band gap in the red light-emitting layer 25R and the electron transport layer 27R. (c) of FIG. 8 and (e) of FIG. 8 illustrate an example of a band gap in the green light-emitting layer 25G and the electron transport layer 27G. (c) of FIG. 8 and (f) of FIG. 8 illustrate an example of a band gap in the blue light-emitting layer 25B and the electron transport layer 27B.

Note that, in FIG. 8, an energy level difference between a LUMO level of the light-emitting layer 25 and a LUMO level of the electron transport layer 27 in each of the red light-emitting element 5R, the green light-emitting element 5G, and the blue light-emitting element 5B is referred to as ER, EL, and EB, respectively. Further, a reference of the energy level in (a) to (c) of FIG. 8 is the same, and similarly, a reference of the energy level in (d) to (f) of FIG. 8 is the same.

Note that the energy band diagram of the present specification illustrates the energy level of each layer with reference to a vacuum level. Further, the energy band diagram of the present specification illustrates a Fermi level or a band gap of a member corresponding to a provided member number.

For example, when the light-emitting layer 25 includes quantum dots as a luminescent body, a wavelength of light from the light-emitting layer 25 can be controlled by controlling a diameter of a core of the quantum dots. In general, the shorter the diameter of the core of the quantum dots, the shorter the wavelength of the light from the light-emitting layer 25 including the quantum dots. The shorter wavelength of the light from the light-emitting layer 25 corresponds to an increase in the band gap of the light-emitting layer 25. Here, as a diameter of the core of the quantum dots changes, a LUMO (CBM) level tends to greatly change in comparison to a change in a HOMO (VBM) level in the band gap of the light-emitting layer 25.

As described above, in the present embodiment, as illustrated in each diagram of FIG. 8, a HOMO (VBM) level 25RH of the red light-emitting layer 25R, a HOMO (VBM) level 25GH of the green light-emitting layer 25G, and a HOMO (VBM) level 25BH of the blue light-emitting layer 25B are substantially the same energy. On the other hand, a LUMO (CBM) level 25BL of the blue light-emitting layer 25B has energy higher than a LUMO (CBM) level 25GL of the green light-emitting layer 25G, and a LUMO level 25GL has energy higher than a LUMO (CBM) level 25RL of the red light-emitting layer 25R.

For example, when the light-emitting layer 25 includes quantum dots including CdSe or ZnSe as the quantum dots, the HOMO level 25RH, the HOMO level 25GH, and the HOMO level 25BH are all approximately −5.5 eV. On the other hand, when the light-emitting layer 25 includes the quantum dots described above, the LUMO level 25RL is approximately −3.4 eV, the LUMO level 25GL is approximately −3.1 eV, and the LUMO level 25BL is approximately −2.7 eV.

The display device according to the comparative embodiment is different from the display device 2 according to the present embodiment in a configuration only in a point that the electron transport layer 27 is formed to be common to all of the pixels. Thus, as illustrated in (a) to (c) of FIG. 8, a HOMO level 27H and a LUMO level 27L of the electron transport layer 27 are the same in all of the light-emitting elements. For example, when the electron transport layer 27 includes ZnO, the HOMO level 27H is approximately −7.2 eV, and the LUMO level 27L is approximately −3.9 eV.

Thus, the energy level difference EB is greater than the energy level difference EG, and the energy level difference EG is greater than the energy level difference ER. In the example described above, the energy level difference ER is approximately 0.5 eV, the energy level difference EG is approximately 0.8 eV, and the energy level difference EB is approximately 1.2 eV.

As a result, the efficiency of electron injection from the electron transport layer 27 to the blue light-emitting layer 25B is reduced further than the efficiency of electron injection from the electron transport layer 27 to the green light-emitting layer 25G. Similarly, the efficiency of electron injection from the electron transport layer 27 to the green light-emitting layer 25G is reduced further than the efficiency of electron injection from the electron transport layer 27 to the red light-emitting layer 25R. Therefore, in the display device according to the comparative embodiment, the electron injection efficiency from the electron transport layer 27 to the light-emitting layer 25 is not optimized between the light-emitting elements different from each other.

In the display device 2 according to the present embodiment, the electron transport layer 27 is formed individually in each of the pixels. Thus, the pixels can have HOMO levels and LUMO levels of the electron transport layer 27 different from each other.

For example, in the present embodiment, as illustrated in (d) of FIG. 8 and (e) of FIG. 8, an energy level of a LUMO level 27GL of the electron transport layer 27G can be set higher than an energy level of a LUMO level 27RL of the electron transport layer 27R. Similarly, as illustrated in (e) of FIG. 8 and (f) of FIG. 8, an energy level of a LUMO level 27BL of the electron transport layer 27B can be set higher than the energy level of the LUMO level 27GL. Note that, also in the present embodiment, a HOMO level 27RH of the electron transport layer 27R, a HOMO level 27GH of the electron transport layer 27G, and a HOMO level 27BH of the electron transport layer 27B may all have substantially the same energy level.

Therefore, in the display device 2 according to the present embodiment, the energy level difference EB and the energy level difference EG can be reduced in comparison to the display device according to the comparative embodiment. Thus, in the display device 2 according to the present embodiment, the electron injection efficiency from the electron transport layer 27 to the light-emitting layer 25 can be more easily optimized between the light-emitting elements different from each other.

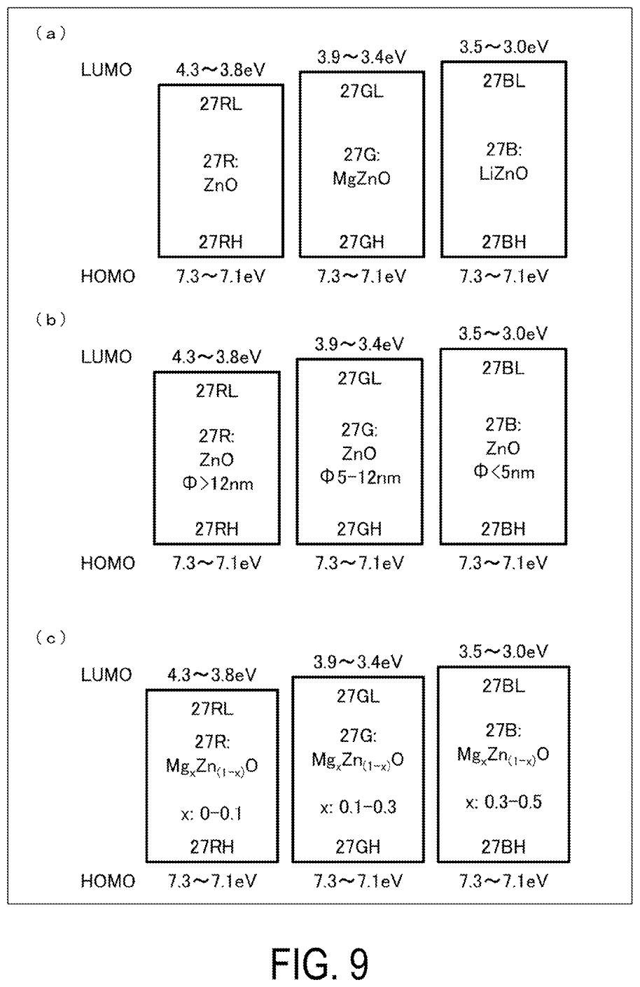

A specific example of the band gap of each of the electron transport layers 27 when the pixels have HOMO levels and LUMO levels of the electron transport layer 27 different from each other will be described with reference to FIG. 9.

In the present embodiment, the LUMO level of the electron transport layer 27 in each of the light-emitting elements may be set different by setting a different material included in each of the electron transport layers 27 between the light-emitting elements different from each other.

For example, the electron transport layer 27R may include ZnO nanoparticles as the oxide nanoparticles. Further, the electron transport layer 27G may include MgZnO nanoparticles as the oxide nanoparticles. Furthermore, the electron transport layer 27B may include LiZnO nanoparticles as the oxide nanoparticles. (a) of FIG. 9 illustrates an example of the band gap of each of the electron transport layers 27 when each of the electron transport layers 27 has the material described above.

In the present embodiment, the pixels may have HOMO levels and LUMO levels of the electron transport layer 2.7 different from each other, and each of the electron transport layers 27 may have the same material. For example, in the present embodiment, each of the electron transport layers 27 may include the same oxide nanoparticle material between the light-emitting elements different from each other. Here, by setting a different particle size of the oxide nanoparticles included in each of the electron transport lavers 27, the band gap of each of the electron transport layers 27 may be set different.

For example, the electron transport layer 27 may also include ZnO nanoparticles as the oxide nanoparticles in all of the light-emitting elements. Here, a particle size of the ZnO nanoparticles in the electron transport layer 27R may be greater than a particle size of the ZnO nanoparticles of the electron transport layer 27G, and a particle size of the ZnO nanoparticles of the electron transport layer 27G may be greater than a particle size of the ZnO nanoparticles of the electron transport layer 27B. Specifically, the particle size of the ZnO nanoparticles of the electron transport layer 27R may be greater than 12 nm, the particle size of the ZnO nanoparticles of the electron transport layer 27G may be equal to or greater than 5 nm and equal to or less than 12 nm, and the particle size of the ZnO nanoparticles of the electron transport layer 27B may be less than 5 nm. (b) of FIG. 9 illustrates an example of the band gap of each of the electron transport layers 27 when each of the electron transport layers 27 has ZnO nanoparticles and the ZnO nanoparticles have the particle size described above.

Furthermore, for example, in the present embodiment, a band gap of each of the electron transport layers 27 may be set different by setting a different composition ratio of the oxide nanoparticles included in each of the electron transport layers 27 between the light-emitting elements different from each other. For example, with x as a real number of equal to or greater than 0 and less than 1, the electron transport layer 27 may include MgₓZn₁₋ₓO nanoparticles as the oxide nanoparticles in all of the light-emitting elements. Here, the value of x may gradually increase in order of the electron transport layer 27R, the electron transport layer 27G, and the electron transport layer 27B.

Specifically, the value of x may be equal to or greater than 0 and less than 0.1 in the electron transport layer 27R, the value of x may be equal to or greater than 0.1 and less than 0.3 in the electron transport layer 27G, and the value of x may be equal to or greater than 0.3 and equal to or less than 0.5 in the electron transport layer 27B. (b) of FIG. 9 illustrates an example of the band gap of each of the electron transport layers 27 when each of the electron transport layers 27 has MgₓZn₁₋ₓO nanoparticles and the MgₓZn₁₋ₓO nanoparticles have the composition described above.

In the present embodiment, when the electron transport layer 27 has any of the configurations described above, an energy level of the LUMO level 27GL can be set higher than an energy level of the LUMO level 27RL, as illustrated in each diagram of FIG. 9. Similarly, when the electron transport layer 27 has any of the configurations described above, an energy level of the LUMO level 27BL can be set higher than an energy level of the LUMO level 27GL.

Even when the electron transport layer 27 has any of the configurations described above, the HOMO level 27RH, the HOMO level 27GH, and the HOMO level 27BH may be all from −7.3 to −7.1 eV as illustrated in each diagram of FIG. 9. Similarly, in the present embodiment, the LUMO level 27RL may be −4.3 to −3.8 eV, the LUMO level 27GL may be −3.9 to −3.4 eV, and the LUMO level 27BL may be −3.5 to −3.0 eV.

In the present embodiment, the second electrode 28 includes a metal nanowire, and thus has high translucency. Thus, a resonator effect is less likely to occur between the first electrode 22 and the second electrode 28. Therefore, it is not necessary to design a film thickness of the electron transport layer 27 in consideration of the occurrence of the resonator effect, and it is possible to more easily achieve the optimization of the electron injection efficiency described above.

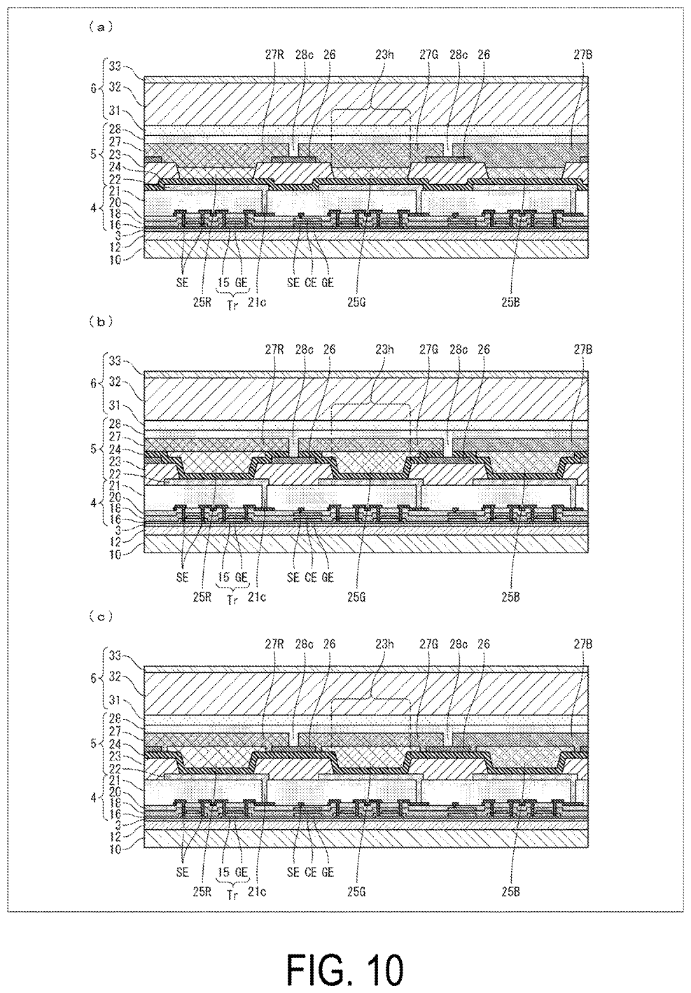

Each diagram of FIG. 10 is a diagram each illustrating a side cross-sectional view of the display device 2 according to a modification example of the present embodiment, and is a side cross-sectional view illustrating the position corresponding to (b) of FIG. 1. The display device 2 according to the modification example of the present embodiment is different in a configuration only in a point that a formation position of the edge cover 23 is different.

As illustrated in (a) of FIG. 10, in the modification example of the present embodiment, the edge cover 23 may be formed as a layer between the hole transport layer 24 and the light-emitting layer 25. In this case, the edge cover 23 includes the opening 23h for each of the plurality of light-emitting elements, and a part of the hole transport layer 24 is exposed from the edge cover 23.

The display device 2 illustrated in (a) of FIG. 10 may be manufactured by the same method as the manufacturing method for the display device 2 according to the present embodiment, except that step S4-6 and step S4-7 illustrated in FIG. 5 are executed between step S4-3 and step S4-4.

Further, as illustrated in (b) of FIG. 10, in another modification example of the present embodiment, the edge cover 23 may be formed as a layer between the first electrode 22 and the hole transport layer 24. In this case, the edge cover 23 includes the opening 23h for each of the plurality of light-emitting elements, and a part of each of the first electrodes 22 is exposed from the edge cover 23. Further, the edge cover 23 covers the end portion of each of the first electrodes 22. Note that, in the display device 2 illustrated in (b) of FIG. 10, the contact hole in which the contact portion 28c is formed is also formed in the hole transport layer 24 overlapping the edge cover 23.

The display device 2 illustrated in (b) of FIG. 10 may be manufactured by the same method as the manufacturing method for the display device 2 according to the present embodiment, except that step S4-6 to step S4-9 illustrated in FIG. 5 are executed between step S4-2 and step S4-3.

Furthermore, as illustrated in (c) of FIG. 10, in another modification example of the present embodiment, the auxiliary wiring line 26 may be formed on an upper face of the hole transport layer 24 in comparison to the modification example illustrated in (b) of FIG. 10. In this case, the contact hole in which the contact portion 28c is formed may not be formed in the hole transport layer 24, and may be formed only in the electron transport layer 27.

The display device 2 illustrated in (c) of FIG. 10 may be manufactured by the same method as the manufacturing method for the display device 2 according to the present embodiment, except that only step S4-6 and step S4-7 illustrated in FIG. 5 are executed between step S4-2 and step S4-3.

### Second Embodiment

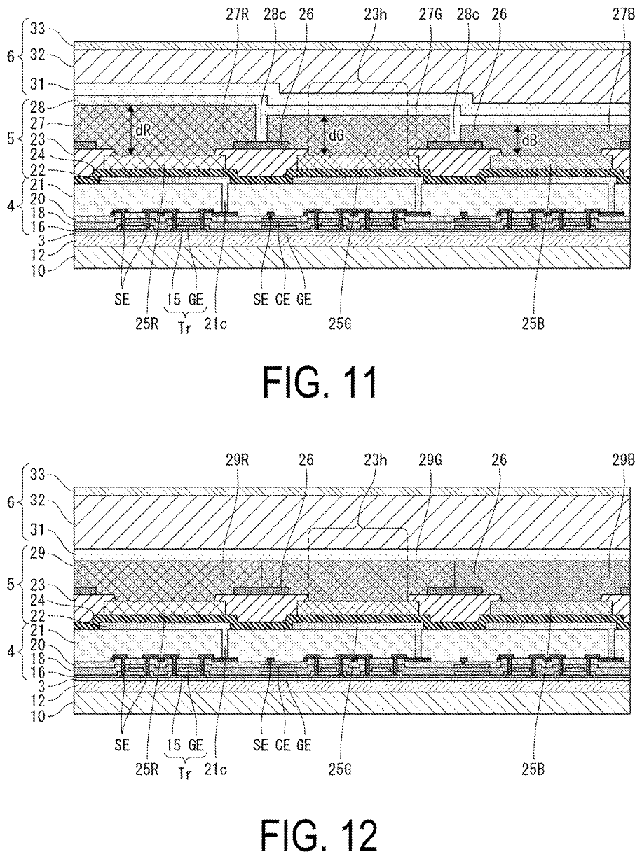

FIG. 11 is a diagram illustrating each side cross-sectional view of a display device 2 according to the present embodiment, and is a side cross-sectional view illustrating the position corresponding to (b) of FIG. 1. The display device 2 according to the present embodiment is different from the display device 2 according to the previous embodiment in a configuration only in a point that an electron transport layer 27R, an electron transport layer 27G, and an electron transport layer 27B have film thicknesses different from each other. Specifically, a film thickness dR of the electron transport layer 27R is greater than a film thickness dG of the electron transport layer 27G, and the film thickness dG is greater than a film thickness dB of the electron transport layer 27B.

The display device 2 according to the present embodiment may be manufactured by the same method as the manufacturing method for the display device 2 according to the previous embodiment. Here, the display device 2 according to the present embodiment may be manufactured by patterning the electron transport layer 27 so as to set a different film thickness of the electron transport layer 27 for each light-emitting element in step S4-10 and step S4-11 illustrated in FIG. 5.

Provided that a current density of a current flowing through the electron transport layer 27 of any light-emitting element of the display device 2 according to the present embodiment is J, an equation (1) below holds true by the Child's law.

J=9εᵣε_{0μe}V²/8d³ (1)

Here, εᵣ is a relative dielectric constant of the electron transport layer 27 to the vacuum, and ε₀ is a vacuum dielectric constant. μₑ is a mobility of electrons in the electron transport layer 27. V is a voltage applied to the electron transport layer 27. d is a film thickness of the electron transport layer 27.

Therefore, according to the equation (1) described above, the smaller the film thickness of the electron transport layer 27, the greater the current density of the current flowing through the electron transport layer 27. Thus, by setting the film thickness dR greater than the film thickness dG and setting the film thickness dG greater than the film thickness dB, the current density of the current flowing through the electron transport layer 27G and the electron transport layer 27B can be increased further than the current density of the current flowing through the electron transport layer 27R.

By increasing the current density of the current flowing through the electron transport layer 27R, the density of electrons injected from the electron transport layer 27 to a light-emitting layer 25 increases. Therefore, according to the configuration described above, the electron injection efficiency from the electron transport layer 27 to the light-emitting layer 25 between the light-emitting elements due to a difference in the energy level difference between the electron transport layer 27 and the light-emitting layer 25 can be optimized.

Note that, also in the present embodiment, a material included in each of the electron transport layers 27 may be set different between the light-emitting elements. By setting both of a different film thickness and a different material in the electron transport layers 27 different from each other, the electron injection efficiency from the electron transport layer 27 to the light-emitting layer 25 can be more efficiently optimized between the light-emitting elements.

Note that, also in the present embodiment, as described above, a resonator effect is less likely to occur between a first electrode 22 and a second electrode 28. Therefore, a design of a film thickness of the electron transport layer 27 does not have to take the occurrence of the resonator effect into consideration, and a film thickness of each of the electron transport layers 27 can be more appropriately designed.

### Third Embodiment

FIG. 12 is a diagram illustrating each side cross-sectional view of a display device 2 according to the present embodiment, and is a side cross-sectional view illustrating the position corresponding to (b) of FIG. 1. The display device 2 according to the present embodiment is different from the display device 2 according to each of the embodiments described above in a configuration only in a point that an electron transport layer 29 is provided instead of the electron transport layer 27 and the second electrode 28.

Similarly to the electron transport layer 27, the electron transport layer 29 is formed for each of a plurality of light-emitting elements in a position overlapping each first electrode 22. In the present embodiment, the electron transport layer 29 includes an electron transport layer 29R for a red light-emitting element 5R, an electron transport layer 29G for a green light-emitting element 5G, and an electron transport layer 29B for a blue light-emitting element 5B.

The electron transport layer 29 includes both of the material provided in the electron transport layer 27 described above and the material provided in the second electrode 28 described above. For example, the electron transport layer 29 includes a photosensitive material and oxide nanoparticles, and further includes a metal nanowire dispersed in the photosensitive material. Thus, the electron transport layer 29 also functions as a counter electrode corresponding to the first electrode 22. In other words, the display device 2 according to the present embodiment may be regarded to have a structure in which the electron transport layer 27 and the second electrode 28 in the display device 2 according to each of the embodiments described above are the same electron transport layer 29.

The display device 2 according to the present embodiment may be manufactured by the same method as the manufacturing method for the display device 2 according to each of the embodiments described above. However, in the present embodiment, the electron transport layer 29 including the function of the second electrode is formed in step S4-10 and step S4-11 illustrated in FIG. 5, and thus step S4-12 and step S4-13 are omitted. Note that, in step S4-10 and step S4-11, any of the electron transport layers 29 may be formed in a frame region NA.

In the present embodiment, since the electron transport layer 29 functions as the second electrode, a configuration of a light-emitting element layer 5 is more simplified. Thus, in the present embodiment, the manufacturing step of the display device 2 is simpler.

Further, in the present embodiment, an auxiliary wiring line 26 formed on an edge cover 23 is in direct contact with the electron transport layer 29 including the function of the second electrode. Thus, a contact hole does not need to be formed in the electron transport layer 29 for an electrical connection between the auxiliary wiring line 26 and the second electrode. Therefore, in the present embodiment, since the contact hole is not formed, the need for positional accuracy in forming a member such as a light-emitting layer 25 is reduced, and an improvement in resolution of the display device 2 can be more easily achieved.

### Fourth Embodiment

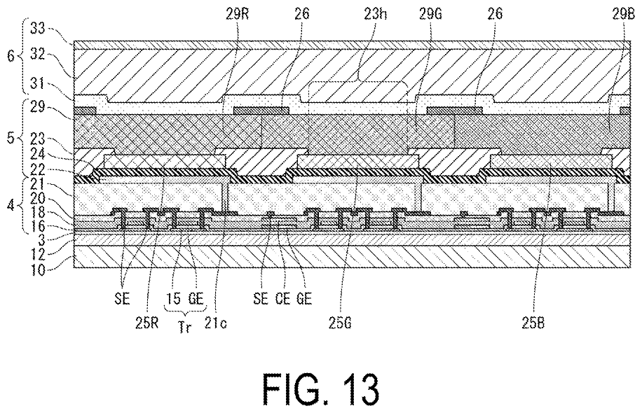

FIG. 13 is a diagram illustrating each side cross-sectional view of a display device 2 according to the present embodiment, and is a side cross-sectional view illustrating the position corresponding to (b) of FIG. 1. The display device 2 according to the present embodiment is different from the display device 2 according to the previous embodiment in a configuration only in a point that an auxiliary wiring line 26 is formed between an electron transport layer 29 and a first inorganic sealing film 31 and is in contact with a sealing layer 6 side of the electron transport layer 29.

The display device 2 according to the present embodiment may be manufactured by the same method as the manufacturing method for the display device 2 according to the previous embodiment, except that step S4-8 and step S4-9 illustrated in FIG. 5 are executed after completion of step S4-11. In other words, after the electron transport layer 29 is formed, the auxiliary wiring line 26 is formed.

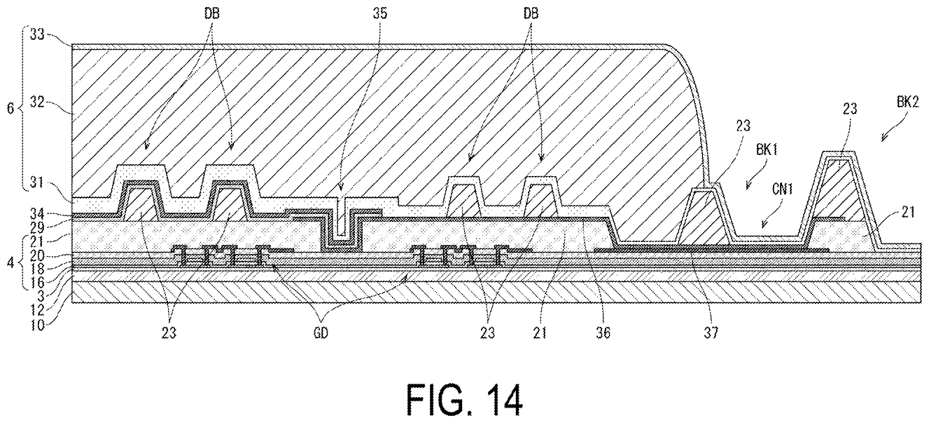

Thus, as illustrated in a side cross-sectional view of the display device 2 according to the present embodiment illustrated in FIG. 14, which corresponds to FIG. 3, the display device 2 according to the present embodiment includes a stem wiring line 34 between the electron transport layer 29 and the first inorganic sealing film 31. Except for the point described above, the display device 2 according to the present embodiment may also have the same configuration as the display device 2 according to the previous embodiment in a frame region NA.

Also in the present embodiment, similarly to the previous embodiment, since a contact hole does not need to be formed in the electron transport layer 29, the need for positional accuracy in forming a member such as a light-emitting layer 25 is reduced, and an improvement in resolution of the display device 2 can be more easily achieved.

Furthermore, in the present embodiment, the auxiliary wiring line 26 is formed. after the formation of the electron transport layer 29. Thus, damage to each of the layers underlying the electron transport layer 29 in the step of patterning the auxiliary wiring line 26 is reduced.

Note that, since the electron transport layer 29 includes a metal nanowire dispersed in a photosensitive resin, the metal nanowire is embedded in the electron transport layer 29. Therefore, in the present embodiment, damage to the metal nanowire in the electron transport layer 29 is reduced in the step of patterning the auxiliary wiring line 26. Thus, a protective film or the like for protecting the electron transport layer 29 does not need to be formed on the electron transport layer 29 for performing the step of patterning the auxiliary wiring line 26.

The light-emitting element layer 5 of the display device 2 according to each of the embodiments described above may have flexibility and be bendable. Each of the embodiments described above describes that, as an example, the light-emitting layer 25 is a quantum dot layer including quantum dots, and the light-emitting element layer 5 includes a quantum dot light emitting diode (QLED) as a light-emitting element. However, no such limitation is intended, and, for example, the light-emitting layer 25 according to each of the embodiments described above may be an organic layer. In other words, the light-emitting element layer 5 according to each of the embodiments described. above may include an organic light-emitting diode (OLED) as a light-emitting element. In this case, the display device 2 according to each of the embodiments may be an organic electro luminescent (EL) display.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

2 Display device
3 Barrier layer
4 Thin film transistor layer
5 Light-emitting element layer
5R Red light-emitting element
5G Green light-emitting element
5B Blue light-emitting element
6 Sealing layer
10 Support substrate
22 First electrode
23 Edge cover
23h Opening
24 Hole transport layer
25 Light-emitting layer
25R Red light-emitting layer
25G Green light-emitting layer
25B Blue light-emitting layer
26 Auxiliary wiring line
28 Second electrode
27, 29 Electron transport layer
DA Display region
NA Frame region

1. A display device comprising:
a display region including a plurality of pixels; and
a frame region around the display region,
wherein a substrate, a thin film transistor layer, a light-emitting element layer including a plurality of light-emitting elements having luminescent colors different from each other, and a sealing layer are provided in the display region in this order,
each of the plurality of light-emitting elements includes a first electrode, a hole transport layer, a light-emitting layer, an electron transport layer, and a second electrode in this order from the substrate side,
the second electrode includes a metal nanowire, and
the electron transport layer includes a photosensitive material and oxide nanoparticles.

2. The display device according to claim 1,
wherein each of the plurality of light-emitting elements includes a red light-emitting element including a red light-emitting layer configured to emit red light in the light-emitting layer, a green light-emitting element including a green light-emitting layer configured to emit green light in the light-emitting layer, and a blue light-emitting element including a blue light-emitting layer configured to emit blue light in the light-emitting layer, and
each of the plurality of pixels includes a red subpixel including the red light-emitting element, a green subpixel including the green light-emitting element, and a blue subpixel including the blue light-emitting element.

3. The display device according to claim 2,
wherein materials of the electron transport layer are different from each other in the red light-emitting element, the green light-emitting element, and the blue light-emitting element.

4. The display device according to claim 3,
wherein the electron transport layer of the red light-emitting element includes ZnO nanoparticles as the oxide nanoparticles, the electron transport layer of the green light-emitting element includes MgZnO nanoparticles as the oxide nanoparticles, and the electron transport layer of the blue light-emitting element includes LiZnO nanoparticles as the oxide nanoparticles.

5. The display device according to claim 2,
wherein the electron transport layer includes ZnO nanoparticles as the oxide nanoparticles, and a particle size of the ZnO nanoparticles gradually decreases in order of the red light-emitting element, the green light-emitting element, and the blue light-emitting element.

6. The display device according to claim 5,
wherein a particle size of the ZnO nanoparticles included in the electron transport layer of the red light-emitting element is greater than 12 nm, a particle size of the ZnO nanoparticles included in the electron transport layer of the green light-emitting element is equal to or greater than 5 nm and equal to or less than 12 nm, and a particle size of the ZnO nanoparticles included in the electron transport layer of the blue light-emitting element is less than 5 nm.

7. The display device according to claim 2,
wherein the electron transport layer includes MgₓZn₁₋ₓO nanoparticles as the oxide nanoparticles, where x is a real number of equal to or greater than 0 and less than 1, and a value of x gradually increases in order of the red light-emitting element, the green light-emitting element, and the blue light-emitting element.

8. The display device according to claim 7,
wherein a value of x in the red light-emitting element is equal to or greater than 0 and less than 0.1, a value of x in the green light-emitting element is equal to or greater than 0.1 and less than 0.3, and a value of x in the blue light-emitting element is equal to or greater than 0.3 and equal to or less than 0.5.

9. The display device according to claim 2,
wherein a film thickness of the electron transport layer of the red light-emitting element, a film thickness of the electron transport layer of the green light-emitting element, and a film thickness of the electron transport layer of the blue light-emitting element are different from each other.

10. The display device according to claim 9,
wherein a film thickness of the electron transport layer gradually decreases in order of the red light-emitting element, the green light-emitting element, and the blue light-emitting element.

11. The display device according to claim 2,
wherein the light-emitting element layer further includes an edge cover configured to divide each of the plurality of pixels into the red subpixel, the green subpixel, and the blue subpixel.

12. The display device according to claim 11,
wherein the light-emitting layer is provided on the substrate side of the edge cover, and the electron transport layer is provided on the sealing layer side of the edge cover.

13. The display device according to claim 12,
wherein the edge cover includes, for each of the plurality of light-emitting elements, a plurality of openings exposing the light-emitting layer, and covers an end portion of the light-emitting layer.

141. The display device according to claim 11,
wherein the edge cover includes, for each of the plurality of light-emitting elements, a plurality of openings exposing the hole transport layer.

15. The display device according to claim 11,
wherein the edge cover includes, for each of the plurality of light-emitting elements, a plurality of openings exposing the first electrode, and covers an end portion of the first electrode.

16. The display device according to claim 11,
wherein the light-emitting element layer further includes an auxiliary wiring line in a lattice pattern in a position overlapping the edge cover, and the auxiliary wiring line and the second electrode are electrically connected to each other.

17. The display device according to claim 16,
wherein the auxiliary wiring line is in contact with the sealing layer side of the edge cover.

18. The display device according to claim 16,
wherein the auxiliary wiring line is in contact with the sealing layer side of the second electrode.

19. The display device according to claim 1,
wherein the second electrode and the electron transport layer are in a same layer, and the electron transport layer includes the metal nanowire dispersed in the photosensitive material.

20. The display device according to claim 1,
wherein the photosensitive material contains a resin material including a polyimide resin, an acrylic resin, an epoxy resin, or a novolac resin, and a photoinitiator including a quinone diazide compound, a photoacid generator, or a photoradical generator.

21. (canceled)

22. (canceled)

23. (canceled)
